(19) United States
(12) Patent Application Publication
(10) Pub. No.: US 2008/0264684 A1
(43) Pub. Date: Oct. 30, 2008

(54) Carrier member for transmitting circuits, coreless printed circuit board using the carrier member, and method of manufacturing the same

(75) Inventors: Myung Sam Kang, Gyunggi-do (KR); Byoung Youl Min, Gyunggi-do (KR); Je Gwang Yoo, Gyunggi-do (KR); Jung Hyun Park, Gyunggi-do (KR); Chang Sup Ryu, Gyunggi-do (KR); Jin Yong Ahn, Daejeon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/003,669

(22) Filed: Dec. 28, 2007

(30) Foreign Application Priority Data
Apr. 30, 2007 (KR) 10-2007-0042002

(51) Int. Cl. H05K 3/10; H05K 1/00; H05K 1/11

(52) U.S. Cl. 174/262; 29/846; 174/250

(57) ABSTRACT

Disclosed herein is a carrier member for transmitting circuits, which is a component of a coreless printed circuit board having circuit patterns embedded therein, and which can be used to provide a high-density and highly reliable printed circuit board by forming protrusions only on the lower ends of the circuit patterns, a coreless printed circuit board using the carrier member, and methods of manufacturing the carrier member and the coreless printed circuit board.

### CROSS REFERENCE TO RELATED APPLICATION

This application claims the benefit of Korean Patent Application No. 10-2007-0042002, filed on Apr. 30, 2007, entitled “Carrier Member for Transmitting Circuits, Coreless Printed Circuit Board Using said Carrier Member, and Methods of Manufacturing the Same,” which is hereby incorporated by reference in its entirety into this application.

### BACKGROUND OF THE INVENTION

1. Field of the Invention

The present invention relates to a carrier member for transmitting circuits, a coreless printed circuit board using the carrier member, and methods of manufacturing the carrier member and the coreless printed circuit board. More particularly, the present invention relates to a carrier member for transmitting circuits, which is a component of a coreless printed circuit board having circuit patterns embedded therein, and which can be used to provide a high-density and highly reliable printed circuit board by forming protrusions only on the lower ends of the circuit patterns, a coreless printed circuit board using the carrier member, and methods of manufacturing the carrier member and the coreless printed circuit board.

2. Description of the Related Art

Examples of the currently used package substrates to which a high-density technology is applicable include FCBGA Flip Chip Ball Grid Array) substrates, most of which are used for CPUs and chipsets. With the increase in mobile applications, package substrates are increasingly required to be configured for CPUs and chipsets.

In order to satisfy the requirement, the package substrates for use in mobile applications must have very high density structures than those of conventional ones, which incurs the technical problem of decreasing the size and thickness of the substrates.

In relation to this fact, hereinafter, a conventional method of building up a printed circuit board using a semi-additive process will be described with reference to FIGS. 5A to 5D.

First, inner layer circuits 502, which are formed on both surfaces of a first resin insulation layer 501, for example, a FR-4 resin substrate impregnated with a glass fiber, are electrically interconnected through a plated through hole 503, using a conventional core circuit layer forming process, such as a subtractive process, a modified semi-additive process (MSAP), or the like. Subsequently, in order to form an outer layer circuit, the inner layer circuits 502 and the plated through hole 503 are layered with a second resin insulation layer 504, for example, an ABF resin substrate not impregnated with glass fiber, the second resin insulation layer 504 is formed with blind via holes 505, and then a copper seed layer 506 is formed on the resin insulation layer 504 through an electroless copper plating process (see FIG. 5A). Subsequently, a dry film 507 is applied at predetermined locations on the copper seed layer 506 other than at the locations at which the outer layer circuits including the blind via holes 505 are to be formed (see FIG. 5B), followed by the formation of a patterned copper plated layer 508 through an electrolytic copper plating process with the applied dried film 507 serving as a plating resist (see FIG. 5C). Then, the dry film 507 is removed from the copper seed layer 506, and then the unnecessary portion of the copper seed layer 506 is removed through a flash etching process, thereby completing an outer layer circuit (see FIG. 5D).

FIG. 6 shows a schematic circuit shape of the printed circuit board manufactured through the above conventional method.

Referring to FIG. 6, circuit patterns 602 and 604 are formed on resin insulation layers 601 and 603, respectively. A circuit 604 and a via 605 are simultaneously realized through a plating process. In this case, the surfaces of the circuit patterns 602 and 604 are generally roughened to increase the adhesivity between the circuit patterns 602 and 604 and the insulation layers 601 and 603. However, as shown in the right side of FIG. 6, when a resin insulation layer 611 is flash-etched to remove a copper seed layer 612 formed thereon, there is a decrease in circuit reliability, such as a short circuit, not only because an electrolytic plated layer 613, as well as the copper seed layer 612, is etched to some extent such that the circuit size is negatively influenced (D1), but also because the lower portion of the circuit is excessively etched such that the area of the circuit is reduced (D2).

### SUMMARY OF THE INVENTION

Accordingly, in order to solve the above problems occurring in the prior art, research has been continuously conducted. As a result, it became possible to manufacture high-density and highly reliable coreless printed circuit boards by transmitting circuit patterns to a resin insulation layer and then embedding them therein using a carrier member for transmitting circuits which is manufactured such that it has circuit patterns protruding only at the outer upper end thereof The present invention has been completed based on this fact.

In a first aspect, the present invention provides a carrier member for transmitting circuits, which can be used to transmit circuit patterns, having protrusions only in the predetermined portion thereof, to a resin insulation layer and to embed them therein without damaging a circuit.

In a second aspect, the present invention provides a method of manufacturing the carrier member for transmitting circuits.

In a third aspect, the present invention provides a coreless printed circuit board having circuit patterns embedded in a resin insulation layer.

In a fourth aspect, the present invention provides a method of manufacturing the coreless printed circuit board using the carrier member for transmitting circuits.

A method of manufacturing a carrier member for transmitting circuits according to a first embodiment of the present invention may include providing a double-sided carrier structure including a thermal adhesive that does not exhibit adhesivity at the time of heat treatment, carrier layers adhered on both sides of the thermal adhesive, and barrier layers formed on the respective carrier layers, in which the barrier layers are metal seed layers, other than copper seed layers; applying plating resists on the respective barrier layers except circuit forming portions thereof, each of the circuit including or not including a land; forming circuit patterns on the circuit forming portions exposed by the plating resists through an electrolytic copper plating process; roughening exposed surfaces of the circuit patterns to form protrusions thereon; and separating a pair of carrier members for transmitting circuits from the thermal adhesive by removing the plating resists and then heat-treating the double-sided carrier structure.

In the method of manufacturing a carrier member, each of the carrier layers may be composed of a metal or a polymer.

The double-sided carrier structure may be heat-treated at a temperature of 100˜150° C.

Meanwhile, the deviation in the width of the circuit patterns may be in the range of ±10%.

In each of the circuit forming portions, first layer land formed on the first carrier member of the pair of carrier members may be divided by a via hole forming portion, and a second layer land formed on the second carrier member thereof may be integrally formed such that it faces the first layer land.

A carrier member for transmitting circuits according to a second embodiment of the present invention may include a carrier layer; a barrier layer, which is a metal seed layer, other than a copper seed layer, formed on the carrier layer; and circuit patterns, including or not including a land, wherein protrusions are not formed on bottom surface and side surfaces of each of the circuit patterns, but rather are formed only on top surface thereof.

A method of manufacturing a coreless printed circuit board according to a third embodiment of the present invention may include (A) providing a pair of carrier members, each of the carrier members comprising a carrier layer, a barrier layer, which is a metal seed layer, other than a copper seed layer, formed on the carrier layer, and circuit patterns including a land, in which protrusions are not formed on bottom surface and side surfaces of each of the circuit patterns, but rather are formed only on top surface thereof; (B) providing a resin insulation layer; (C) orienting the pair of carrier members to face each other such that each of the carrier members faces the resin insulation layer and then embedding the circuit patterns into the resin insulation layer; (D) removing the carrier layers to expose the barrier layers; (E) forming a via hole for interlayer electrical connection to expose the surface of the land contacting the via hole; (F) forming a copper seed layer on each of the barrier layers and the surface of the via hole; (G) filling the via hole through a plating process; (H) etching surface layers including the copper seed layers to expose the barrier layers; and (I) etching surface layers including the barrier layers to expose the circuit patterns.

In the method of manufacturing a coreless printed circuit board, the steps of (C) to (I) may be performed through a sheet type process.

The resin insulation layer may be formed of a thermosetting resin impregnated or not impregnated with a reinforcing material.

Each of the carrier layers may be removed through a peeling process or an etching process.

Each of the copper seed layers may be formed through an electroless copper plating process.

Meanwhile, a first layer land formed on the first carrier member of the pair of carrier members may be divided by a via hole forming portion, and a second layer land formed on the second carrier member thereof may be integrally formed such that it faces the first layer land.

In this case, the via hole may be formed by removing the barrier layer corresponding to the via forming portion to expose the resin insulation layer and then treating the resin insulation layer to expose the surface of the lands contacting the via hole.

The method of manufacturing a coreless printed circuit board may further include forming outer circuit layers on one side or both sides of the coreless printed circuit board one or more times, wherein the forming the outer circuit layers includes providing a second carrier member for transmitting circuits including a second carrier layer, a second barrier layer formed on the carrier layer, and a second circuit pattern including or not including a land, in which protrusions are not formed on bottom surface and side surfaces of the second circuit pattern, but are formed only on top surface thereof; layering a second resin insulation layer on one side or both side of the coreless printed circuit board; orienting the second circuit pattern of the second carrier member to face the second resin insulation layer and then embedding the second circuit pattern into the second resin insulation layer; removing the second carrier layer to expose the second barrier layer; forming a second via hole for interlayer electrical connection to expose the surface of the second land, contacting the second via hole; forming a second copper seed layer on the second barrier layer and the surface of the second via hole; filling the second via hole through a plating process; etching a surface layer including the second copper seed layers to expose the second barrier layers; and etching a surface layer including the second barrier layer to expose the second circuit pattern.

A coreless printed circuit board according to a fourth embodiment of the present invention may include a resin insulation layer; circuit patterns, including lands, embedded in both sides of the resin insulation layer, each surface of the circuit patterns being exposed; and a via formed such that it contacts the land of each layer to achieve interlayer electrical connection, wherein protrusions are not formed on side surfaces of the exposed and embedded surfaces of the circuit patterns including the lands, but are formed only on bottom surfaces thereof, and the circuit patterns and the via are different from each other in a layer configuration.

Here, each of the circuit patterns, including the lands, may be formed of an electrolytic copper plating layer, and the via may be formed of an electroless copper foil seed layer formed on the inner surface thereof and a filled plating layer formed on the electroless copper foil seed layer.

The coreless printed circuit pattern may further include a second resin insulation layer placed on one side or both sides of the coreless printed circuit board; second circuit patterns, including second lands, interposed in the second resin insulation layer, each surface of the second circuit patterns being exposed; and a second via formed such that it contacts the second land of each layer to achieve interlayer electrical connection, wherein protrusions are not formed on side surfaces of the exposed and interposed surface of the second circuit patterns including or not including the land, and are formed only on bottom surfaces thereof, and the second circuit patterns and the second via are different from each other in a layer configuration.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a schematic sectional view showing a structure of a coreless printed circuit board according to an embodiment of the present invention;

FIGS. 2A and 2B are schematic sectional views showing structures of multi-layered coreless printed circuit boards according to an embodiment of the present invention;

FIGS. 3A to 3E are sectional views illustrating a process of manufacturing a carrier member for transmitting circuits according to an embodiment of the present invention;

FIGS. 4A to 4G are sectional views illustrating a process of manufacturing a coreless printed circuit board according to an embodiment of the present invention;

FIGS. 5A to 5D are sectional views illustrating a conventional process of manufacturing a printed circuit board; and

FIG. 6 is a sectional view illustrating the shape of the printed circuit board manufactured using the conventional process for manufacturing a printed circuit board.

### DESCRIPTION OF THE PREFERRED EMBODIMENTS

Hereinafter, preferred embodiments of the present invention will be described in detail with reference to the attached drawings.

Reference now should be made to the drawings, in which the same reference numerals are used throughout the different drawings to designate the same or similar components.

FIG. 1 is a schematic sectional view showing a structure of a coreless printed circuit board according to an embodiment of the present invention.

The coreless printed circuit board according to an embodiment of the present invention, which is a thin structure with circuits embedded in resin, can be used as a core structure of a high-density substrate.

Referring to FIG. 1, the coreless printed circuit board 100 includes a resin insulation layer 101; circuit patterns 102 and 104, including lands 103 and 105, the surfaces of which are exposed, and which are embedded in respective sides of the resin insulation layer 101; and a via 106 contacting the lands 103 and 105 for interlayer electrical connection.

The resin insulation layer 101 may be formed of a thermosetting resin impregnated or not impregnated with a reinforcing material. For example, a prepreg, FR-4, bismaleimide triazine (BT), Ajinomoto build up film (ABF), or the like, which is formed of an epoxy resin, may be used for the resin insulation layer 101, but the invention is not limited thereto. Generally, when the resin insulation layer 101 is used for a double-sided substrate, a prepreg is used for the resin insulation layer 101, and when it is used for a multi-layered substrate, a thermosetting resin, not impregnated with glass fiber, is used for the resin insulation layer 101, but when it is used for a multi-layered substrate requiring a predetermined strength, a thermosetting resin impregnated with a glass fiber may be used for the resin insulation layer 101.

The circuit patterns 102 and 104, including lands 101 and 105, are layered on the resin insulation layer 101, and are then cured and embedded therein. The width (D) of each of the circuit patterns 101 and 104 is substantially equal to the space (E) therebetween. The width (D) of each of the circuit patterns 101 and 104 and the space (E) therebetween may be selected in the range of 5˜15 μm so that the circuit pattern 101 and 104 can be applied to a high-density thin substrate. The deviation in the widths of the circuit patterns 101 and 104 may be in the range of ±10%.

According to the present invention, no protrusions are formed on the exposed surface and embedded side surfaces (I) of each of the circuit patterns, including the lands 103 and 105, which are exposed and embedded in the resin insulation layer 101, rather, they are formed only on the embedded bottom surface (J) thereof. The protrusion may have, but is not limited to, a needle shape and an anchor shape.

The thickness (B or B′) of each of the circuit patterns 102 and 104, including the lands 103 and 105, is not particularly limited as long as electrical conduction is not problematic, and the insulation distance (C) between the circuit patterns 102 and 104 is not particularly limited, as long as it is long enough to prevent the occurrence of circuit migration therebetween.

Meanwhile, the configuration of each of the circuit pattern 102 and 104 is different from that of the via 106.

Each of the circuit patterns 102 and 104, including the lands 103 and 105, may be formed of an electrolytic copper plated layer, and the via 106 may include an electroless copper foil seed layer 106a formed on the surface thereof and a plated layer 106b formed in the electroless copper-foil seed layer 106a.

The size (F or F′) of each of the lands 103 and 105 is roughly equal to the sum of the via size (G) and two times annular ring size (H). For example, in order to apply the lands 103 and 105 to a high-density thin substrate, the via size (G) may be set in the range of about 40˜65 μm, and the annular ring size (H) may be set in the range of 10˜30 μm. In this case, the size (F or F′) of each of the lands 103 and 105 may be (40˜65 μm)+(10˜30 μm)×2≈60˜125 μm, but is not limited thereto.

Meanwhile, there is a step (K or K′) between the one surface of the resin insulation layer 101 and the exposed surface of each of the circuit patterns 101 and 104, including the lands 103 and 105.

The total thickness (A) of the coreless printed circuit board according to an embodiment of the present invention may be a maximum of 60 μm.

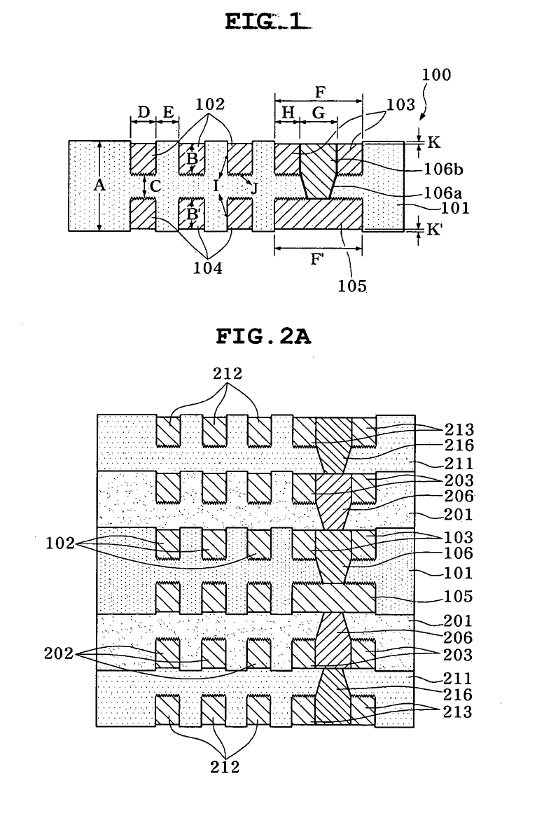

FIGS. 2A and 2B are schematic sectional views showing structures of multi-layered coreless printed circuit boards according to an embodiment of the present invention.

In the multi-layered coreless printed circuit board according to the present invention, an outer layer is built on an inner layer, with the same structure as in either side of the inner layer given thereto. Particularly as for a high multilayer structure, the outer layers are built so as to maintain a symmetry in architecture.

First, a six-layered coreless printed circuit board will be described with reference to FIG. 2A. The six-layered coreless printed circuit board includes resin insulation layers 201 formed on both sides of the coreless printed circuit board 100 shown in FIG. 1, as first outer layers; second circuit patterns 202, including lands 203, the surfaces of which are exposed, and which are embedded in respective second resin insulation layers 201; and vias 206 contacting the lands 203 to achieve interlayer electrical connection. Further, the six-layered coreless printed circuit board includes third resin insulation layers 211 formed on respective sides of the first outer layers, as second outer layers; third circuit patterns 212, including lands 213, the surfaces of which are exposed, and which are embedded into respective third resin insulation layers 211; and vias 216 contacting the lands 213 to achieve interlayer electrical connection.

In each of the first outer layers, no protrusions are formed on the exposed surface and embedded side surfaces of each of the second circuit patterns 202, including the lands 203, which are exposed and embedded in each of the second resin insulation layers 201, rather, they are formed only on the embedded bottom surface thereof. Meanwhile, the configuration of each of the second circuit patterns 202 is different from that of the via 206. This characteristic of the first outer layer is equally applied to the second outer layer.

The structural specification, such as materials, circuit patterns and vias, which is used in the coreless printed circuit board of FIG. 1, can be applied substantially equally to the outer layers of the multi-layered coreless printed circuit board. In the present invention, although a double-sided six-layered coreless printed circuit board has been described, if necessary, various multi-layered coreless printed circuit boards can be manufactured, and single-sided multi-layered coreless printed circuit boards can also be manufactured.

FIG. 2B shows a four-layered coreless printed circuit board not including lands 203 in the uppermost layers. The structural specification, such as materials, circuit patterns and vias, in the four-layered coreless printed circuit board is the same as that of the six-layered coreless printed circuit board shown in FIG. 2A, except that the uppermost layers thereof have no lands.

Meanwhile, a carrier member for transmitting circuits, which is used to manufacture the coreless printed circuit board, according to an embodiment of the present invention, includes a carrier layer a barrier layer formed on the carrier layer, and a circuit pattern including or not including a land. In this case, no protrusions are formed on the exposed side surfaces or bottom surface of the circuit pattern 202, including or not including a land, rather, they are formed only on the exposed top surface thereof.

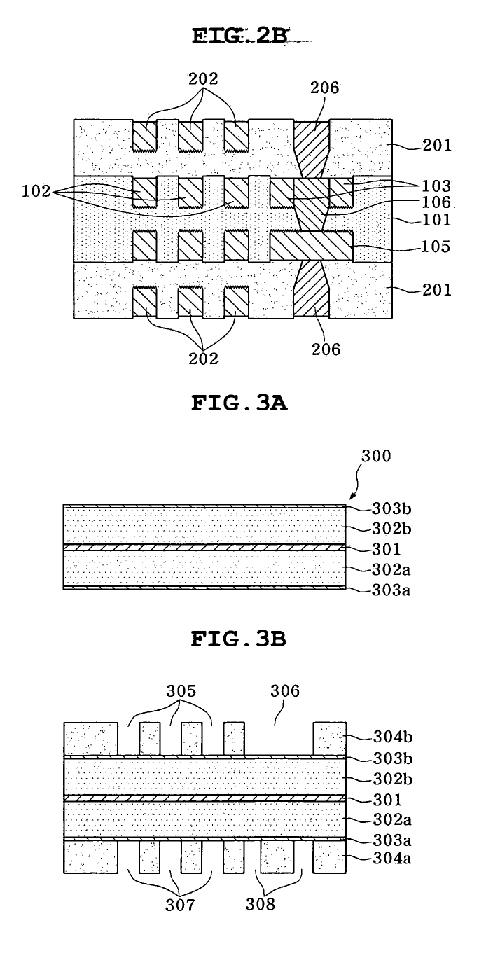

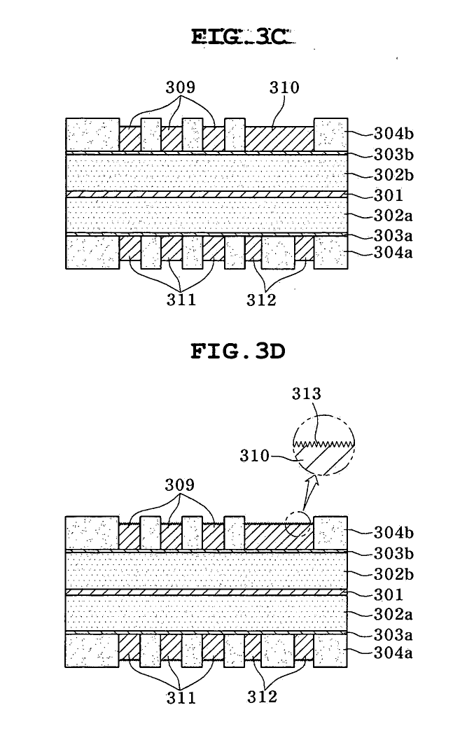

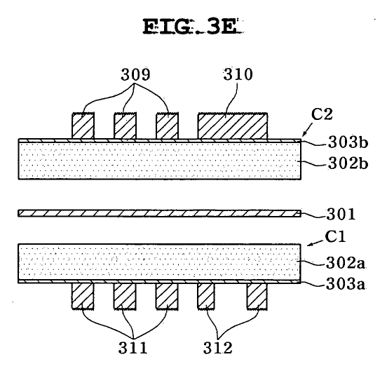

Hereinafter, a method of manufacturing the carrier member for transmitting circuits according to an embodiment of the present invention will be described with reference to FIGS. 3A to 3E.

First, a double-sided carrier structure 300, including a thermal adhesive 301, carrier layers 302a and 302b adhered on both sides of the thermal adhesive 301, and barrier layers 303a and 303b formed on the carrier layers 302a and 302b, is provided (see FIG. 3A).

The thermal adhesive 301 is a material that does not exhibit adhesivity at the time of heat treatment. All thermal adhesives commonly known in the art can be used as the thermal adhesive 301 as long as they maintain high adhesivity at room temperature, but lose the adhesivity through heat treatment, thus enabling them to be easily separated from an adherend. Examples of the thermal adhesive 301 may include, but are not limited to, a thermal additive including an acrylic resin and a foaming agent, which does not exhibit adhesivity at the time of heat treatment at a temperature of about 100˜150° C. or similar.

The carrier layers 302a and 302b may be formed of materials commonly known in the art, such as metals, polymers, and particularly strippable polymers, without limitation.

The barrier layers 303a and 303b may be formed of materials commonly known in the art, such as nickel, chromium, and combinations thereof, rather than copper, without limitation. Further, the thickness of the barrier layers 303a and 303b and the method of forming the same are not particularly limited. For example, the barrier layers 303a and 303b can be formed to a thickness of about 3˜5 μm through electrolytic or electroless plating, but the invention is not limited thereto.

Subsequently, plating resists 304a and 304b are applied on the barrier layers 303a and 303b of the double-sided carrier structure 300, other than circuit forming portions 305, 306, 307 and 308, the circuit including or not including a land (see FIG. 3B). The plating resists 304a and 304b may be formed of materials commonly known in the art without limitation. For example, only the circuit forming portions can be exposed through general exposure and etching processes using a dry film as the plating resist.

In this case, the circuit forming portions 305, 306, 307 and 308 are selected such that a first layer land 312, patterned on one of the carrier members for transmitting circuits, is divided by a via hole forming portion while a second layer land 310, facing the first land 312, is integrally formed.

Then, the circuit forming portions 305, 306, 307 and 308 exposed through plating resists 304a and 304b are formed into circuit patterns 309, 310, 311 and 312 by performing an electrolytic copper plating process (see FIG. 3C). In this case, since barrier layers 303a and 303b are preformed, the electrolytic copper plating process can be directly performed without forming additional seed layers.

Subsequently, the exposed surfaces of the circuit patterns are roughened, thus forming protrusions 313 thereon (see FIG. 3D). The roughening of the surfaces of the circuit patterns may be conducted without limitation using any method as long as it is a method for improving adhesivity between a resin insulation layer and a circuit layer that is known in the art, and the protrusion may have, but is not limited to, a needle shape or an anchor shape.

Next, the plating resists 304a and 304b are removed through a peeling process, and then the double-sided carrier structure 300 is heat-treated at a temperature of 100˜150° C., thus obtaining a pair of carrier members C1 and C2 for transmitting circuits, which are separated from the thermal adhesive 301. In the pair of carrier members C1 and C2 for transmitting circuits, the structural specification of the circuit patterns 309 and 311, including the lands 310 and 312, is the same as that shown in FIG. 1.

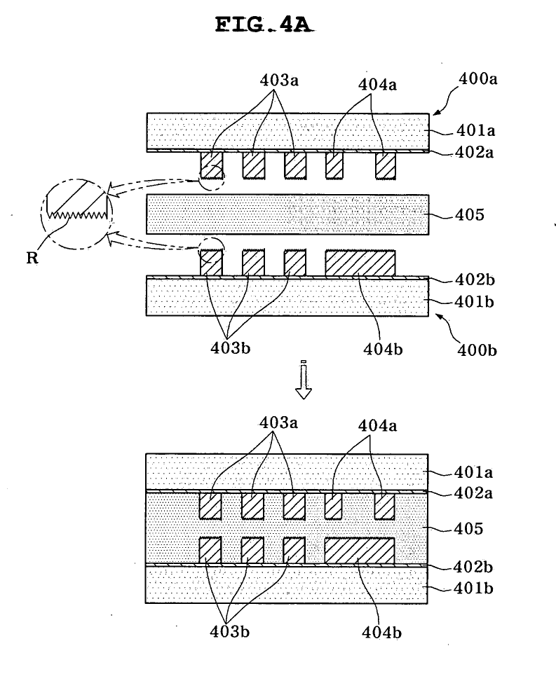

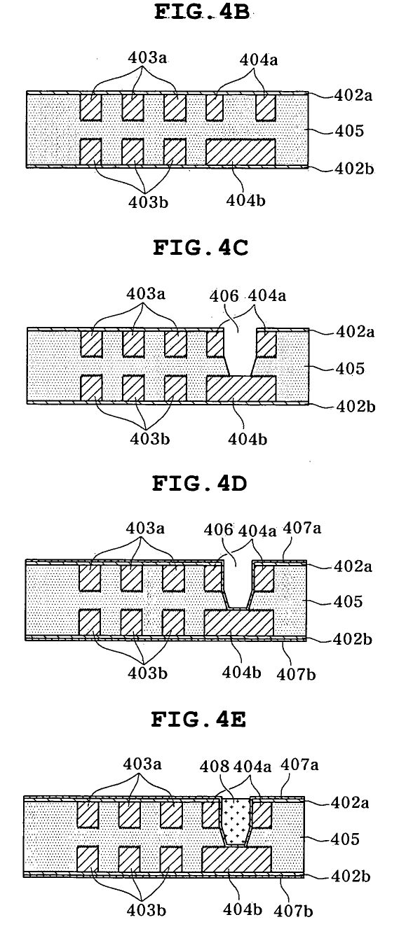

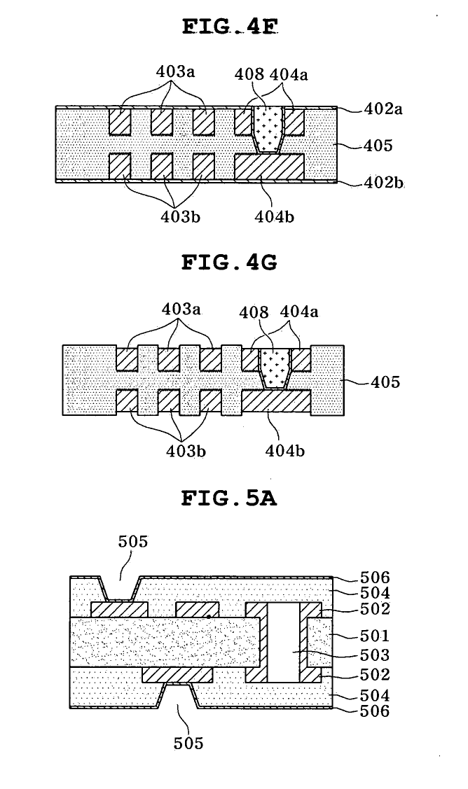

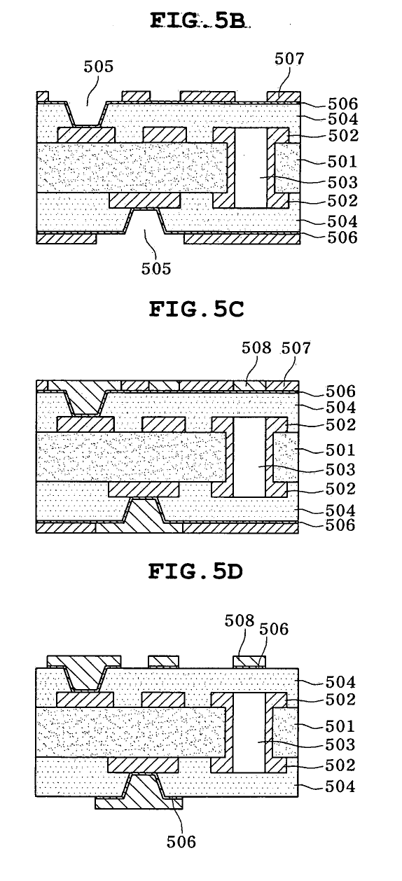

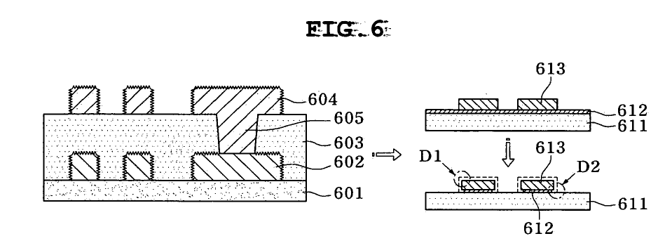

Hereinafter, a method of manufacturing a coreless printed circuit pattern using the carrier member for transmitting circuits according to an embodiment of the present invention will be described with reference to FIGS. 4A to 4G.

First, a pair of carrier members 400a and 400b for transmitting circuits, which include carrier layers 401a and 401b, barrier layers 402a and 402b formed on the carrier layers 401a and 401b, and circuit patterns 403a and 403b, including lands 404a and 404b, formed on the barrier layers 402a and 402b, respectively, is provided. In this case, the first layer land 404a, which is formed on the first carrier member 400a of the pair of carrier members 400a and 400b, is patterned into two spaced parts, with a via hole area interposed therebetween such that both side surfaces of a via hole 406 come into contact with the inner side surfaces thereof. Meanwhile, the second layer land 404b, which is formed on the second carrier member 400b of the pair of carrier members 400a and 400b, is integrally formed in opposition to the first layer land 404a such that the inner upper end thereof comes into contact with the lower end of the via hole 406. In this case, no protrusions (R) are formed on the inner lower ends and exposed side surfaces of the circuit patterns 403a and 403b, including the lands 404a and 404b, and protrusions are formed only on the outer upper ends thereof.

Then, a resin insulation layer 404 is located between the carrier members 400a and 400b. The circuit patterns 403a and 403b and lands 404a and 404b of the pair of carrier members 400a and 400b face each other, and are then embedded into the resin insulation layer 405 (FIG. 4A). In this case, the pair of carrier members 400a and 400b is layered on the resin insulation layer 405 such that they face each other, the resin insulation layer 405 is cured, and then the circuit patterns 403a and 403b and lands 404a and 404b of the pair of carrier members 400a and 400b are embedded into the resin insulation layer 405.

Subsequently, the carrier layers 401a and 401b are removed from the carrier members 400a and 400b, respectively, thus exposing the barrier layers 402a and 402b (see FIG. 4B). The carrier layers 401a and 401b are removed through a peeling process when they are formed of strippable polymers, and they are removed through an etching process when they are formed of metallic materials, but the present invention is not limited thereto.

Next, a via hole 406 for interlayer electrical connection is formed to expose the surfaces of the lands 404a and 404b contacting the via hole 406 (see FIG. 4C). In this case, the via hole 406 may be formed using a general CO₂ laser. Preferably, the via hole 406 may be formed by removing the barrier layer 402a, located at a via hole forming portion, to expose the resin insulation layer 405, and then treating the resin insulation layer 405 to expose the surfaces of the lands 404a and 404b contacting the via hole forming portion.

Subsequently, copper seed layers 407a and 407b are formed on the inner side of the via hole 406 and the respective barrier layers 402a and 402b (see FIG. 4D). The copper seed layers 407a and 407b may be formed through an electroless copper plating process, but are not limited thereto. Prior to the electroless copper plating process, general surface pretreatment, for example, desmearing treatment, may be performed in order to remove impurities.

Next, the via hole is filled using a method of plating for filling a via hole (see FIG. 4E). The method of plating for filling the via hole is not particularly limited, but it is preferred that a plating layer be formed only in the via hole and that it not be formed on the surface of a substrate, by appropriately adjusting the component of a plating solution and selecting a suitable plating method, as in reverse pulse plating.

Subsequently, surface layers including the copper seed layers 407a and 407b are etched using a flash etching method, thus exposing the barrier layers 402a and 402b (see FIG. 4F). Then surface layers, including the barrier layers 402a and 402b, are also etched using a metal etching method, thus exposing the circuit patterns 403a, 403b, 404a and 404b (see FIG. 4G). In this case, the damage to the copper circuit pattern can be decreased when barrier layers, composed of metals other than copper, are etched and thus removed according to the present invention, compared to when copper seed layers are etched using conventional etching methods. Meanwhile, since the surfaces of circuit patterns are generally finely etched in a process of etching the barrier layers 402a and 402b, there may be a step between the surface of the resin insulation layer 405 and the surface of the circuit patterns.

According to the present invention, since the strength of a coreless printed circuit board can be maintained at a predetermined level while manufacturing the coreless printed circuit board, the process of manufacturing the coreless printed circuit board can be performed in a line designed for a small contact area against an operation roll, that is, in a sheet-type process.

In the present invention, only a printed circuit board having a core structure has been illustrated. However, a multi-layered printed circuit board can also be realized by repeating several time the steps of layering a second resin insulation layer on one or both sides of the coreless printed circuit board using another carrier member, manufactured as shown in FIGS. 3A to 3E, embedding second circuit patterns into the second resin insulation layer and then transmitting them thereto, and forming a via hole for interlayer connection. In this case, if necessary, via lands need not be formed in the outer most layers.

As described above, since the printed circuit board according to the present invention has a structure in which circuits are embedded in an insulation layer, a thin printed circuit board having fine circuits without a core can be realized. Further, in the printed circuit board of the present invention, since only the inner lower ends of the circuits embedded in the insulation layer are roughened to increase the adhesivity between the circuits and the insulation layer, damage to the circuits can be minimized and the reliability of the circuits can thus be increased.

Furthermore, in the printed circuit board of the present invention, since circuit layers are interposed in one insulation layer, a high-density thin printed circuit board can be manufactured.

As described above, the coreless printed circuit board according to the present invention is advantageous in that the damage to circuits is minimized at the time of removing seed layers in the realization of fine circuits. Further, the coreless printed circuit board is advantageous in that, since protrusions are formed only on the inner lower ends of the circuit embedded into the insulation layer, the damage to the circuits can be minimized and simultaneously the reliability of the circuits can be increased.

Furthermore, in the present invention, a thin printed circuit board having fine circuits without a core can be realized by forming circuits using carrier members and then transmitting the circuits to the carrier members and embedding the circuits into an insulation layer. Further, in the present invention, additional apparatuses for driving a thin printed circuit board are not required because the strength of the printed circuit board is maintained at a predetermined level in manufacturing lines, and the printed circuit board can be manufactured through a sheet type process.

Moreover, the coreless printed circuit board according to the present invention is advantageous in that since the surface thereof is flatter than that of a conventional printed circuit board, ICs can be easily mounted thereon.

As described above, although the preferred embodiments of the present invention have been described in detail, a carrier member for transmitting circuits, a coreless printed circuit board manufactured using the carrier member, and methods of manufacturing the carrier member and the coreless printed circuit board are not limited thereto, and those skilled in the art will appreciate that various modifications, additions and substitutions are possible, without departing from the scope and spirit of the invention as disclosed in the accompanying claims.

What is claimed is:

1. A method of manufacturing a carrier member for transmitting circuits, comprising:
providing a double-sided carrier structure including a thermal adhesive that does not exhibit adhesivity at the time of heat treatment, carrier layers adhered on both sides of the thermal adhesive, and barrier layers formed on the respective carrier layers, in which the barrier layers are metal seed layers, other than copper seed layers;
applying plating resists on the respective barrier layers except circuit forming portions thereof, each of the circuit including or not including a land;
forming circuit patterns on the circuit forming portions exposed by the plating resists through an electrolytic copper plating process;
roughening exposed surfaces of the circuit patterns to form protrusions thereon; and
separating a pair of carrier members for transmitting circuits from the thermal adhesive by removing the plating resists and then heat-treating the double-sided carrier structure.

2. The method of manufacturing a carrier member for transmitting circuits according to claim 1, wherein each of the carrier layers is composed of a metal or a polymer.

3. The method of manufacturing a carrier member for transmitting circuits according to claim 1, wherein the double-sided carrier structure is heat-treated at a temperature of 100˜150° C.

4. The method of manufacturing a carrier member for transmitting circuits according to claim 1, wherein deviation in width of the circuit patterns is in a range of ±10%.

5. The method of manufacturing a carrier member for transmitting circuits according to claim 1, wherein, in each of the circuit forming portions, a first layer land formed on the first carrier member of the pair of carrier members is divided by a via hole forming portion, and a second layer land formed on the second carrier member thereof is integrally formed such that it faces the first layer land.

6. A carrier member, comprising:
a carrier layer;
a barrier layer, which is a metal seed layer, other than a copper seed layer, formed on the carrier layer; and
circuit patterns, including or not including a land,
wherein protrusions are not formed on bottom surface and side surfaces of each of the circuit patterns, but rather are formed only on top surface thereof.

7. The carrier member according to claim 6, wherein the carrier layer is composed of a metal or a polymer.

8. The carrier member according to claim 6, wherein deviation in width of the circuit patterns is in a range of ±10%.

9. A method of manufacturing a coreless printed circuit board, comprising:
(A) providing a pair of carrier members, each of the carrier members comprising a carrier layer, a barrier layer, which is a metal seed layer, other than a copper seed layer, formed on the carrier layer, and circuit patterns including a land, in which protrusions are not formed on bottom surface and side surfaces of each of the circuit patterns, but rather are formed only on top surface thereof;
(B) providing a resin insulation layer;
(C) orienting the pair of carrier members to face each other such that each of the carrier members faces the resin insulation layer and then embedding the circuit patterns into the resin insulation layer;
(D) removing the carrier layers to expose the barrier layers;
(E) forming a via hole for interlayer electrical connection to expose the surface of the land contacting the via hole;
(F) forming a copper seed layer on each of the barrier layers and the surface of the via hole;
(G) filling the via hole through a plating process;
(H) etching surface layers including the copper seed layers to expose the barrier layers; and
(I) etching surface layers including the barrier layers to expose the circuit patterns.

10. The method of manufacturing a coreless printed circuit board according to claim 9, wherein the steps of (C) to (I) are performed through a sheet type process.

11. The method of manufacturing a coreless printed circuit board according to claim 9, wherein each of the carrier layers is composed of a metal or a polymer.

12. The method of manufacturing a coreless printed circuit board according to claim 9, wherein deviation in width of the circuit patterns is in a range of ±10%.

13. The method of manufacturing a coreless printed circuit board according to claim 9, wherein the resin insulation layer is formed of a thermosetting resin impregnated or not impregnated with a reinforcing material.

14. The method of manufacturing a coreless printed circuit board according to claim 9, wherein each of the carrier layers is removed through a peeling process or an etching process.

15. The method of manufacturing a coreless printed circuit board according to claim 9, wherein each of the copper seed layers is formed through an electroless copper plating process.

16. The method of manufacturing a coreless printed circuit board according to claim 9, wherein first layer land formed on the first carrier member of the pair of carrier members is divided by a via hole forming portion, and a second layer land formed on the second carrier member thereof is integrally formed such that it faces the first layer land.

17. The method of manufacturing a coreless printed circuit board according to claim 9, wherein the via hole is formed by removing the barrier layer corresponding to the via forming portion to expose the resin insulation layer and then treating the resin insulation layer to expose the surface of the lands contacting the via hole.

18. The method of manufacturing a coreless printed circuit board according to claim 9, further comprising forming outer circuit layers on one side or both sides of the coreless printed circuit board one or more times,
wherein the forming the outer circuit layers comprises:
providing a second carrier member for transmitting circuits including a second carrier layer, a second barrier layer formed on the carrier layer, and a second circuit pattern including or not including a land, in which protrusions are not formed on bottom surface and side surfaces of the second circuit pattern, but are formed only on top surface thereof;
layering a second resin insulation layer on one side or both side of the coreless printed circuit board;
orienting the second circuit pattern of the second carrier member to face the second resin insulation layer and then embedding the second circuit pattern into the second resin insulation layer;
removing the second carrier layer to expose the second barrier layer;
forming a second via hole for interlayer electrical connection to expose the surface of the second land, contacting the second via hole;
forming a second copper seed layer on the second barrier layer and the surface of the second via hole;
filling the second via hole through a plating process;
etching a surface layer including the second copper seed layers to expose the second barrier layers; and
etching a surface layer including the second barrier layer to expose the second circuit pattern.

19. A coreless printed circuit board, comprising:
a resin insulation layer;
circuit patterns, including lands, embedded in both sides of the resin insulation layer, each surface of the circuit patterns being exposed; and
a via formed such that it contacts the land of each layer to achieve interlayer electrical connection,
wherein protrusions are not formed on side surfaces of the exposed and embedded surfaces of the circuit patterns including the lands, but are formed only on bottom surfaces thereof, and the circuit patterns and the via are different from each other in a layer configuration.

20. The coreless printed circuit pattern according to claim 19, wherein each of the circuit patterns is formed of an electrolytic copper plating layer, and the via is formed of an electroless copper foil seed layer formed on the inner surface thereof and a filled plating layer formed on the electroless copper foil seed layer.

21. The coreless printed circuit pattern according to claim 19, wherein deviation in width of the circuit patterns is in a range of ±10%.

22. The coreless printed circuit pattern according to claim 19, wherein the resin insulation layer is formed of a thermosetting resin impregnated or not impregnated with a reinforcing material.

23. The coreless printed circuit pattern according to claim 19, further comprising:
a second resin insulation layer placed on one side or both sides of the coreless printed circuit board;
second circuit patterns, including second lands, interposed in the second resin insulation layer, each surface of the second circuit patterns being exposed; and
a second via formed such that it contacts the second land of each layer to achieve interlayer electrical connection,
wherein protrusions are not formed on side surfaces of the exposed and interposed surface of the second circuit patterns including or not including the land, and are formed only on bottom surfaces thereof, and the second circuit patterns and the second via are different from each other in a layer configuration.
